(19) United States
(12) Patent Application Publication
(10) Pub. No.: US 2015/0097119 A1
(43) Pub. Date: Apr. 9, 2015

(54) PHOTOVOLTAIC POWER GENERATION SYSTEM

(71) Applicant: Kabushiki Kaisha Toshiba, Minato-ku (JP)

(72) Inventors: Chihiro KASAI, Bunkyo-ku (JP); Kengo Wakamatsu, Koganei-shi (JP); Masahiro Asayama, Yokohama-shi (JP); Hirofumi Shinohara, Saitama-shi (JP)

(73) Assignee: Kabushiki Kaisha Toshiba, Minato-ku (JP)

(21) Appl. No.: 14/565,700

(22) Filed: Dec. 10, 2014

Related U.S. Application Data
(63) Continuation of application No. 13/491,297, filed on Jun. 7, 2012.
Application No. 13/491,297 is a continuation of application No. PCT/JP10/70605, filed on Nov. 18, 2010.

(30) Foreign Application Priority Data
Dec. 7, 2009 (JP) 2009-277459
Jan. 13, 2010 (JP) 2010-4919

(51) Int. Cl. H01L 27/142

(52) U.S. Cl. CPC H01L 27/142
USPC 250/340

(57) ABSTRACT

According to an embodiment, a solar cell string 8 including solar cell modules 1 connected in series and each configured to generate DC power by being irradiated with light; and a junction box 2 configured to receive the DC power from the solar cell string are included. The junction box includes: a DC detector 10 configured to detect a current flowing through the solar cell string; a measurement device 11 configured to measure a current value of the current detected by the DC detector; and a data transmitter 12 configured to send the current value measured by the measurement device.

### CROSS-REFERENCE TO RELATED APPLICATIONS

This application is a continuation of and claims the benefit of priority under 35 U.S.C. §120 from U.S. Ser. No. 13/491,297 filed Jun. 7, 2012, which is a continuation of PCT Application No. PCT/JP2010-070605 filed on Nov. 18, 2010, and claims the benefit of priority under 35 U.S.C. §119 from Japanese Patent Application No. 2009-277459 filed Dec. 7, 2009 and Japanese Patent Application No. 2010-4919 filed Jan. 13, 2010, the content of all of which is incorporated herein by reference.

### FIELD

Embodiments described herein relate generally to a photovoltaic power generation system configured to generate power using sunlight.

### BACKGROUND

Photovoltaic power generation systems convert DC power generated by solar cell modules irradiated with light into AC power by using an inverter and supply the AC power to an electric power system. Such a photovoltaic power generation system includes solar cell modules, a junction box, an inverter, a step-up transformer, an AC circuit breaker, an interconnection transformer, and an interconnection circuit breaker.

The solar cell modules generate DC power by being irradiated with light. Multiple solar cell modules are connected in series, thus forming a solar cell string. The solar cell string integrates the DC power generated by each of the solar cell modules and outputs the DC power between a positive electrode terminal and a negative electrode terminal. Photovoltaic power generation systems include multiple solar cell strings, and the positive electrode terminal and the negative electrode terminal of each of the solar cell strings are connected to the junction box.

The junction box collects the DC power sent from the multiple solar cell strings and sends the DC power to the inverter. The inverter converts the DC power sent from the junction box into AC power and sends the AC power to the step-up transformer. The step-up transformer converts the AC power sent from the inverter into AC power having a predetermined voltage and sends the AC power to the interconnection transformer via the AC circuit breaker. The interconnection transformer converts the received AC power into power having a voltage suitable for interconnection with system power and sends the power thus converted to the system power via the interconnection circuit breaker. Here, the higher the intensity of light with which a solar cell module is irradiated, the larger the output current of the solar cell module 1, resulting in a larger power obtainable from the photovoltaic power generation system.

### Problems to be Solved by the Invention

The aforementioned conventional photovoltaic power generation system is installed outdoors. Accordingly, unforeseen trouble such as a stain on a surface glass due to bird droppings or damage on a surface glass due to hail occurs in the solar cell modules used in the photovoltaic power generation system. As a result, a problem such as abnormal heat generation of a part of the solar cell modules occurs.

In addition, if such an abnormal solar cell module is left unfixed, there arises a problem that the expected amount of power generation cannot be obtained, causing a delay in the recovery of investment. In addition, a safety problem such as burn damage on the rear surface of the solar cell module occurs due to the abnormal heat generation. Accordingly, maintenance to detect an abnormality in the solar cell modules and identify in which of the solar cell modules the abnormality exists is necessary in the photovoltaic power generation system.

When a problem occurs in any of the solar cell modules, the output power and output current of the solar cell module decreases. Accordingly, it is possible to detect occurrence of a problem by monitoring the output power or output currents. However, the number of solar cell modules increases in a case where a large-scale photovoltaic power generation system that has an output power of 1000 KW or more is used, for example.

Accordingly, a decrease in output due to an abnormality in one solar cell module becomes relatively small, so that it becomes difficult to detect an abnormality in the solar cell modules by monitoring the output power or output currents. Meanwhile, it is possible to identify in which of the solar cell modules an abnormality occurs, by visually observing the solar cell modules and measuring the temperature, current, and voltage thereof one by one. However, an increase in the number of solar cell modules as described above leads to an increase in the time required for the maintenance, thus resulting in an increase in cost.

An objective of the present invention is to provide a photovoltaic power generation system capable of finding an abnormality in solar cell modules and easily identifying an abnormal solar cell module.

### Means for Solving the Problems

To solve the problems, a photovoltaic power generation system of an embodiment includes: a solar cell string including solar cell modules connected in series and each configured to generate DC power by being irradiated with light; and a junction box configured to receive the DC power from the solar cell string. The junction box includes: a DC detector configured to detect a current flowing through the solar cell string; a measurement device configured to measure a current value of the current detected by the DC detector; and a data transmitter configured to send the current value measured by the measurement device.

### BRIEF DESCRIPTION OF THE DRAWINGS

FIG. 1 is a diagram showing a configuration of a main part of a photovoltaic power generation system according to a first embodiment.

FIG. 2 is a diagram showing another configuration of the main part of the photovoltaic power generation system according to the first embodiment.

FIG. 3 is a diagram showing a configuration of a main part of a photovoltaic power generation system according to a second embodiment.

FIG. 4 is a diagram showing another configuration of the main part of the photovoltaic power generation system according to the second embodiment.

FIG. 5 is a diagram showing a configuration of a main part of a photovoltaic power generation system according to a third embodiment.

FIG. 6 is a circuit diagram showing another configuration of the main part of the photovoltaic power generation system according to the third embodiment.

FIG. 7 is a diagram showing a configuration of a main part of a photovoltaic power generation system according to a fourth embodiment.

FIG. 8 is a diagram showing a decrease in the output of a solar cell module according to the first embodiment and the third embodiment decreases.

FIG. 9 is a diagram showing a decrease in the output of a solar cell module according to the second embodiment and the fourth embodiment decreases.

FIG. 10 is a diagram showing a configuration of a main part of a photovoltaic power generation system according to a fifth embodiment.

FIG. 11 is a diagram showing another configuration of a main part of a photovoltaic power generation system according to a sixth embodiment.

FIG. 12 is a diagram for describing an imaging device used in a photovoltaic power generation system according to a seventh embodiment.

FIG. 13 is a lateral view showing a configuration of the photovoltaic power generation system according to the seventh embodiment.

FIG. 14 is a top view showing a configuration of a modification example of the photovoltaic power generation system according to the seventh embodiment.

FIG. 15 is a diagram for describing an example of an operation of the photovoltaic power generation system according to the seventh embodiment.

FIG. 16 is a diagram showing a configuration of another modification example of the photovoltaic power generation system according to the seventh embodiment.

FIG. 17 is a diagram showing a configuration of still another modification example of the photovoltaic power generation system according to the seventh embodiment.

FIG. 18 is a diagram showing a configuration of yet another modification example of the photovoltaic power generation system according to the seventh embodiment.

FIG. 19 is a diagram partially showing a configuration of an intrusion monitoring system used with a photovoltaic power generation system according to an eighth embodiment.

FIG. 20 is a diagram partially showing a configuration of a photovoltaic power generation system configured to search for a high temperature portion of solar cell modules by imaging devices of the intrusion monitoring system shown in FIG. 19.

FIG. 21 is a diagram partially showing a configuration of the photovoltaic power generation system according to the eighth embodiment.

FIG. 22 is a flowchart showing an operation of the photovoltaic power generation system according to the eighth embodiment.

FIG. 23 is a diagram partially showing a configuration of a modification example of the photovoltaic power generation system according to the eighth embodiment.

FIG. 24 is a diagram partially showing a configuration of another modification example of the photovoltaic power generation system according to the eighth embodiment.

FIG. 25 is a diagram partially showing a configuration of still another modification example of the photovoltaic power generation system according to the eighth embodiment.

FIG. 26 is a diagram showing a modification example of the photovoltaic power generation system shown in FIG. 25.

FIG. 27 is a diagram partially showing a configuration of yet another modification example of the photovoltaic power generation system according to the eighth embodiment.

### DETAILED DESCRIPTION

Hereinbelow, embodiments will be described in detail with reference to the drawings.

### First Embodiment

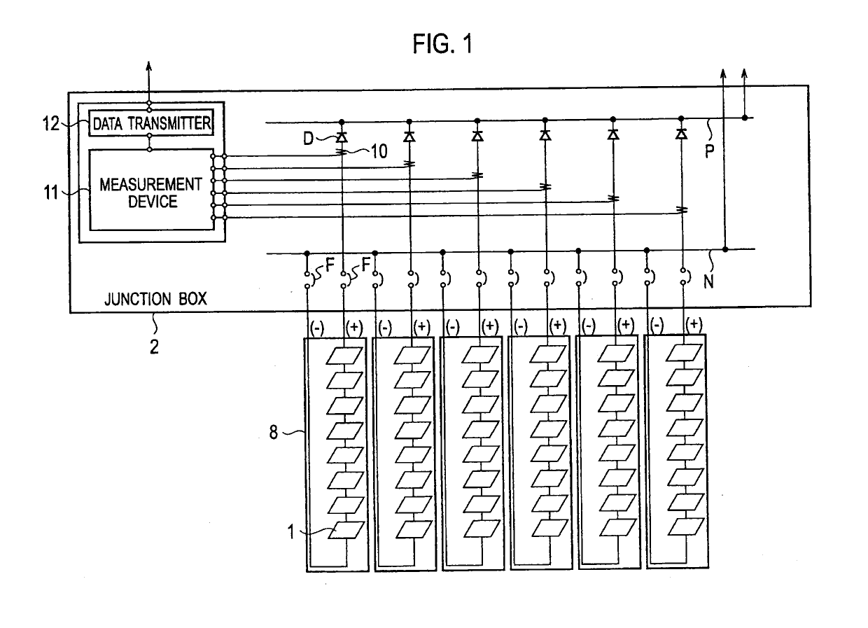

FIG. 1 is a diagram showing a configuration of a main part of a photovoltaic power generation system according to a first embodiment. The photovoltaic power generation system includes solar cell modules, a junction box, an inverter, a step-up transformer, an AC circuit breaker, an interconnection transformer, and an interconnection circuit breaker. Note that, only multiple solar cell strings 8 and a junction box 2 are shown in FIG. 1.

This photovoltaic power generation system is formed by connecting the multiple solar cell strings 8 to the junction box 2. The multiple solar cell strings 8 are each formed of one or multiple solar cell modules 1, which are connected in series.

The junction box 2 includes fuses F, back-flow prevention diodes D, a positive electrode P, a negative electrode N, DC detectors 10, a measurement device 11, and a data transmitter 12. Positive electrode terminals (+) of the respective solar cell strings 8 are connected to the positive electrode P via the fuses F, the DC detectors 10, and the back-flow prevention diodes D, while negative electrode terminals (−) thereof are connected to the negative electrode N via the fuses F. Each of the fuses F melts when an overcurrent flows between a corresponding one of the solar cell strings 8 and the junction box 2 and thereby protects the circuit inside the junction box 2 and the solar cell string 8. Each of the back-flow prevention diodes D prevents the back flow of a current flowing toward the positive electrode P from a corresponding one of the solar cell strings 8.

The DC detectors 10 are each formed of a current transformer, for example, and configured to detect a current flowing out from the positive electrode terminal (+) of a corresponding one of the solar cell strings 8 as a positive value. The current value signal indicating the current value detected by the DC detector 10 is sent to the measurement device 11. The measurement device 11 measures a current value on the basis of the current value signal received from each of the DC detectors 10 and sends the current value to the data transmitter 12. The data transmitter 12 sends current data indicating the current value received from the measurement device 11 to outside via wire or radio.

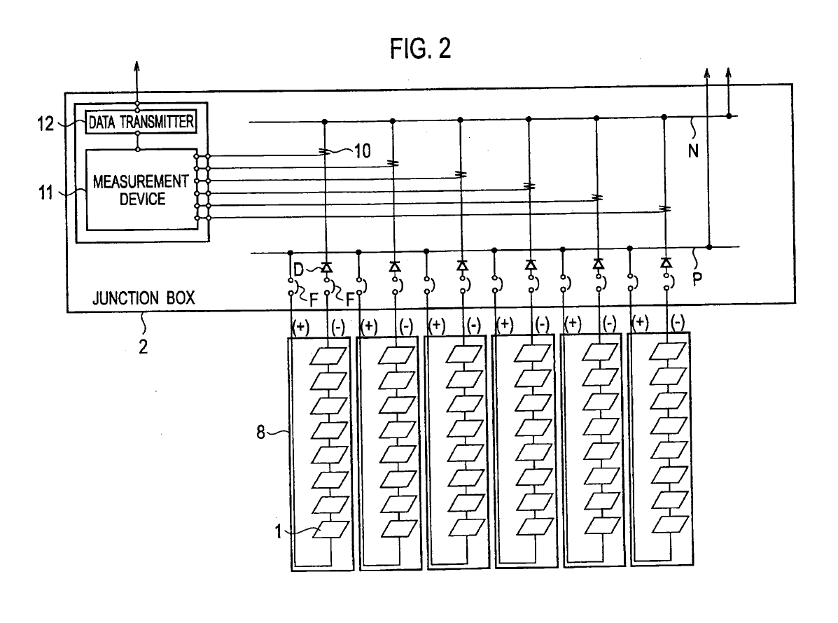

Note that, the DC detectors 10 may be provided on the negative electrode terminal (−) side of the solar cell strings 8 and configured to detect the currents flowing into the negative electrode terminals (−) of the solar cell strings 8 as positive values as shown in FIG. 2.

Next, an operation of the photovoltaic power generation system according to the first embodiment, which has the above configuration, will be described. The power generated by each of the solar cell strings 8 is outputted through a corresponding one of the positive electrode terminals (+) and then supplied to the junction box 2. The currents from the respective solar cell strings 8 flow through the fuses F, the DC detectors 10, the back-flow prevention diodes D, and the positive electrode P in the junction box 2, and then are outputted outside the junction box 2. During this flow, the DC detectors 10 detect the magnitudes of the currents outputted from the respective multiple solar cell strings 8 and send the results of detection to the measurement device 11 as the current value signals. The measurement device 11 measures a current value based on the current value signal from each of the DC detectors 10 and sends the current value to the data transmitter 12. The data transmitter 12 sends the received current value to outside.

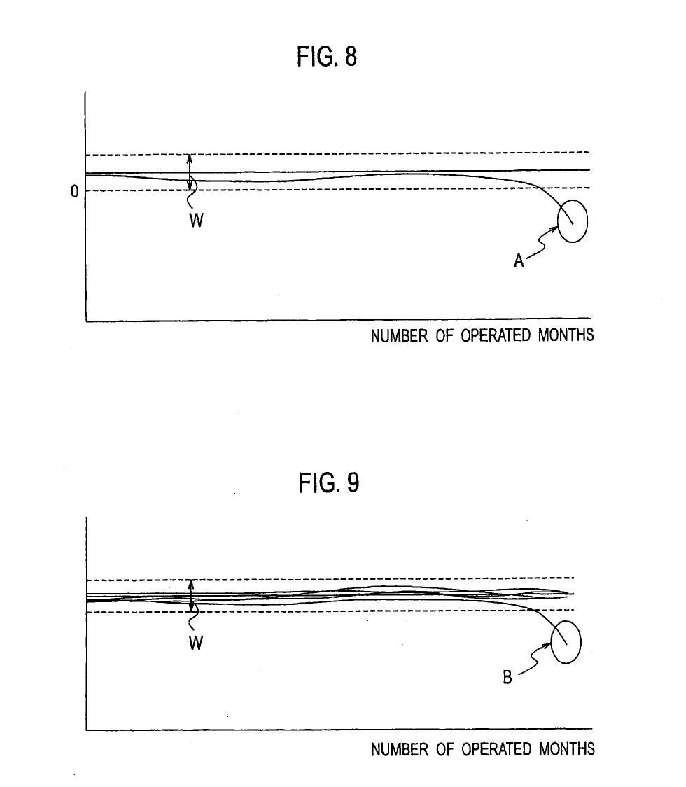

If a solar cell module 1 whose output has decreased exists in any of the solar cell strings 8, the current outputted from the solar cell string 8 including the solar cell module 1 is smaller than the currents outputted from the other solar cell strings 8. As shown in FIG. 8, in a case where the current value detected by any of the DC detectors 10 falls out of an allowable range that is set in accordance with the purpose, the corresponding solar cell string 8 is judged to include the solar cell module 1 whose output has decreased, and is thus detected as abnormal.

As described above, a decrease in the output of the solar cell modules 1, which is difficult to be detected from output of the photovoltaic power generation system, can be instantly detected for each of the solar cell strings 8 in the photovoltaic power generation system according to the first embodiment. In addition, the solar cell string 8 in which the solar cell module 1 whose output has decreased exists can be identified. Thus, the time and cost required for replacement and maintenance work of the solar cell modules 1 can be reduced. Moreover, the instant detection of a decrease in the output of the solar cell modules 1 enables instant replacement of the solar cell module 1 whose output has decreased with another, thus making it possible to suppress a decrease in the amount of power generation which is attributable to a decrease in the output of the solar cell module 1. In addition, since the value of the current flowing through each of the solar cell strings 8 is sent to outside by the data transmitter 12, the photovoltaic power generation system can be monitored remotely.

As described above, with the photovoltaic power generation system according to the first embodiment, a decrease in the output of the solar cell modules 1 is instantly detected for each of the solar cell strings 8. Thus, a period during which the output decreases is reduced, and the recovery of investment is thereby accelerated. Moreover, remote monitoring is made possible, so that the maintenance is made easier, and the operation cost can be thus reduced.

### Second Embodiment

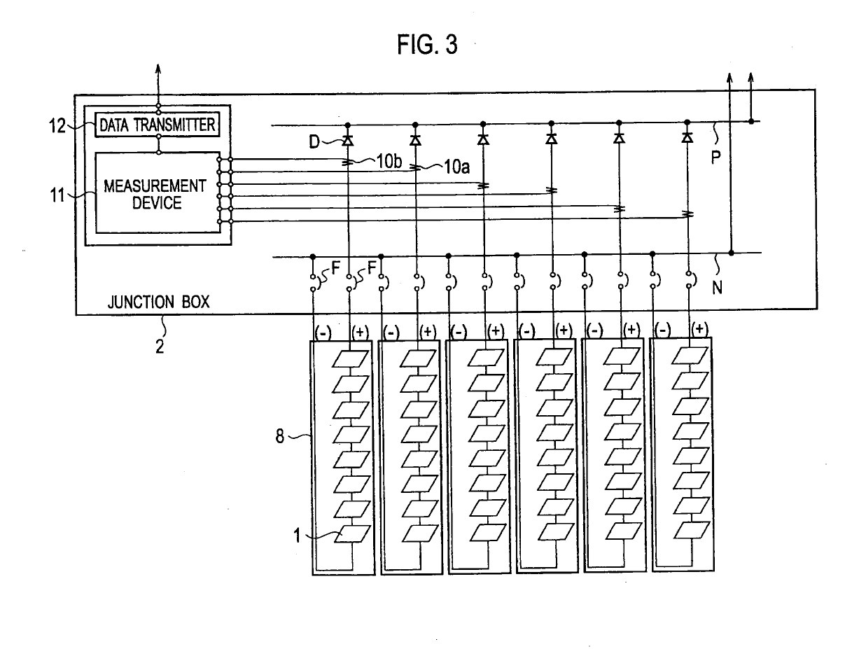

FIG. 3 is a diagram showing a configuration of a main part of a photovoltaic power generation system according to a second embodiment. Note that, only the multiple solar cell strings 8 and the junction box 2 are shown in FIG. 3.

This photovoltaic power generation system is different from the photovoltaic power generation system according to the first embodiment only in the internal configuration of the junction box 2. Accordingly, the portion different from the photovoltaic power generation system according to the first embodiment will be mainly described. In other words, the detectors of only one kind, which are the DC detectors 10, are used to detect the currents outputted from the multiple solar cell strings 8 in the photovoltaic power generation system according to the first embodiment, but two kinds of detectors which are DC detectors 10a and DC detectors 10b are used in the photovoltaic power generation system according to the second embodiment.

Each of the DC detectors 10a corresponds to a first value current detector and is formed of a current transformer, for example, and configured to detect a current flowing out from the positive electrode terminal (+) of a corresponding one of part of, e.g., half of the solar cell strings 8 as a positive value. Each of the DC detectors 10b corresponds to a second value current detector and is formed of a current transformer, for example, and configured to detect a current flowing out from the positive electrode terminal (+) of a corresponding one of the other part of, e.g., the other half of the solar cell strings 8 as a negative value. The current value signals indicating the current values detected by the DC detectors 10a and the DC detectors 10b are sent to the measurement device 11.

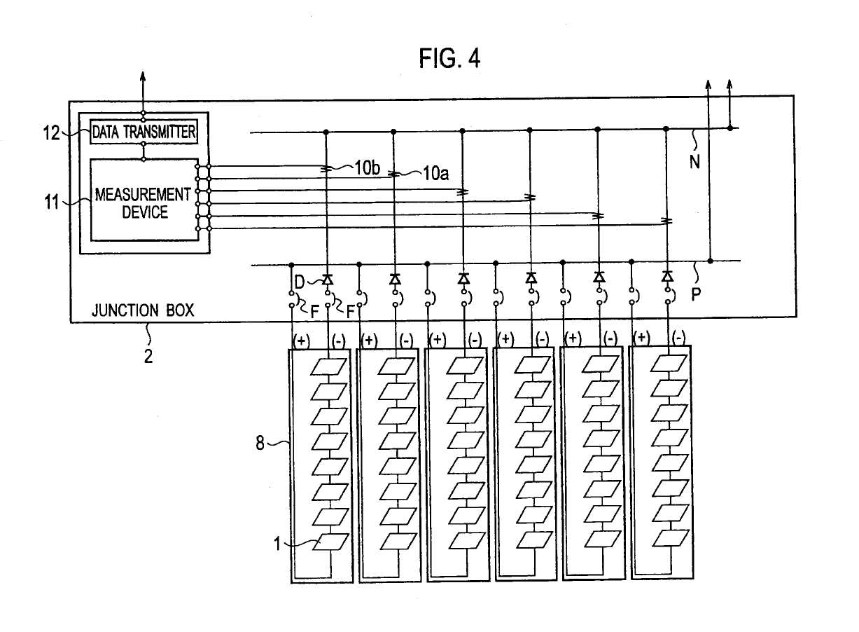

Note that, the DC detectors 10a and the DC detectors 10b may be provided on the negative electrode terminal (−) side of the solar cell strings 8, and the DC detectors 10a may be configured to detect the currents flowing into the negative electrode terminals (−) of the solar cell strings 8 as positive values, and the DC detectors 10b may be configured to detect the currents flowing into the negative electrode terminals (−) of the solar cell strings 8 as negative values as shown in FIG. 4. In this case, the number of DC detectors 10a and the number of DC detectors 10b are preferably the same.

Next, an operation of the photovoltaic power generation system according to the second embodiment, which has the above configuration, will be described. The power generated by each of the solar cell strings 8 is outputted through a corresponding one of the positive electrode terminals (+) and then supplied to the junction box 2. The currents from the respective solar cell strings 8 flow through the fuses F, the DC detectors 10a or the DC detectors 10b, the back-flow prevention diodes D, and the positive electrode P in the junction box 2, and then are outputted outside the junction box 2. During the flow, the DC detectors 10a and the DC detectors 10b detect the magnitudes of the currents outputted from the corresponding multiple solar cell strings 8 and send the results of detection to the measurement device 11 as the current value signals.

The measurement device 11 combines the current values based on the current value signals from the DC detectors 10a and the DC detectors 10b and sends the current value to the data transmitter 12. The data transmitter 12 transmits the received current value to outside. In a case where the photovoltaic power generation system operates normally, the absolute values of the positive values and the negative values of the currents respectively detected by the DC detectors 10a and the DC detectors 10b are almost equal to each other because the amounts of power outputted from the respective solar cell strings 8 are almost equal to each other. In this case, if the number of DC detectors 10a and the number of DC detectors 10b are the same, a total of the current values from the DC detectors 10a and the current values from the DC detectors 10b inputted to the measurement device 11 becomes almost equal to zero.

If a solar cell module 1 whose output has decreased exists in any of the solar cell strings 8, the current outputted from the solar cell string 8 including the solar cell module 1 is smaller than the currents outputted from the other solar cell strings 8. Here, in a case where the solar cell string 8 including the solar cell module 1 whose output has decreased is connected to any of the DC detectors 10a, the total of the current values inputted to the measurement device 11 from the DC detectors 10a and the DC detectors 10b decreases. In a case where the solar cell string 8 including the solar cell module 1 whose output has decreased is connected to any of the DC detectors 10b, the total of the current values inputted to the measurement device 11 from the DC detectors 10a and the DC detectors 10b increases.

Accordingly, as shown in FIG. 9, in a case where the total of the current values inputted to the measurement device 11 from the DC detectors 10a and the DC detectors 10b falls out of an allowable range W set in accordance with the purpose, the photovoltaic power generation system is judged to include a solar cell module 1 whose output has decreased, and is thus detected as abnormal (portion denoted by B in FIG. 9). Upon detection of an abnormality, the solar cell string 8 that has caused the total of the current values to fall out of the allowable range set in accordance with the purpose can be identified by comparing the absolute values of the current values from the DC detectors 10a and the DC detectors 10b.

As described above, the photovoltaic power generation system according to the second embodiment can achieve the functions equivalent to those of the photovoltaic power generation system according to the first embodiment at the equivalent cost. In addition, in comparison with the photovoltaic power generation system according to the first embodiment, which needs to use all the current values outputted from the DC detectors 10, a decrease in the output of any of the solar cell modules 1 can be detected by using only the total value of the current values from the DC detectors 10a and the DC detectors 10b. Thus, the load for detecting a decrease in output can be reduced.

As described above, according to the photovoltaic power generation system according to the second embodiment, a decrease in the output of the solar cell modules 1 is instantly detected for each of the solar cell strings 8. Thus, a period during which the output decreases is reduced, and the recovery of investment is thereby accelerated. Moreover, safety is enhanced by suppressing the influence of heat generation of the solar cell modules 1 due to a decrease in output. Meanwhile, remote monitoring is made possible, so that the maintenance is made easier, and the operation cost can be thus reduced. Furthermore, the load on the system monitoring a decrease in output can be reduced as compared with the photovoltaic power generation system according to the first embodiment.

### Third Embodiment

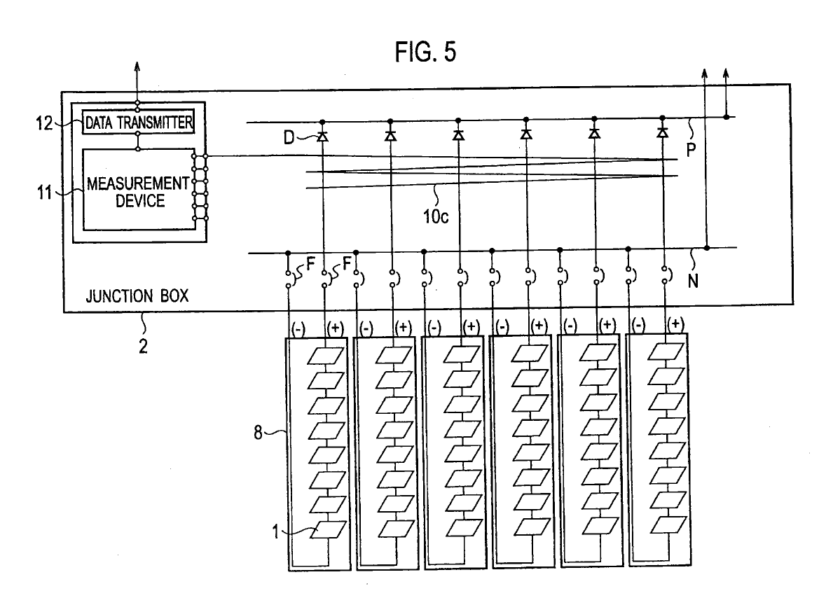

FIG. 5 is a diagram showing a configuration of a main part of a photovoltaic power generation system according to a third embodiment. Note that, only the multiple solar cell strings 8 and the junction box 2 are shown in FIG. 5.

This photovoltaic power generation system is different from the photovoltaic power generation system according to the first embodiment only in the internal configuration of the junction box 2. Accordingly, the portion different from the photovoltaic power generation system according to the first embodiment will be mainly described. To put it specifically, the multiple DC detectors 10 are provided respectively to the multiple solar cell strings 8 in the photovoltaic power generation system according to the first embodiment, but a single DC detector 10c is provided to the multiple solar cell strings 8 in the photovoltaic power generation system according to the third embodiment.

The DC detector 10c is formed of a current transformer, for example, and configured to detect the currents flowing out from the positive electrode terminals (+) of the multiple solar cell strings 8 as positive values. Note that, in a case where multiple DC detectors 10 are each used to detect the currents from the multiple solar cell strings 8, it is preferable to configure each of the DC detectors 10 to detect the same number of solar cell strings 8. The current value signals indicating the current values detected by the DC detector 10c are sent to the measurement device 11.

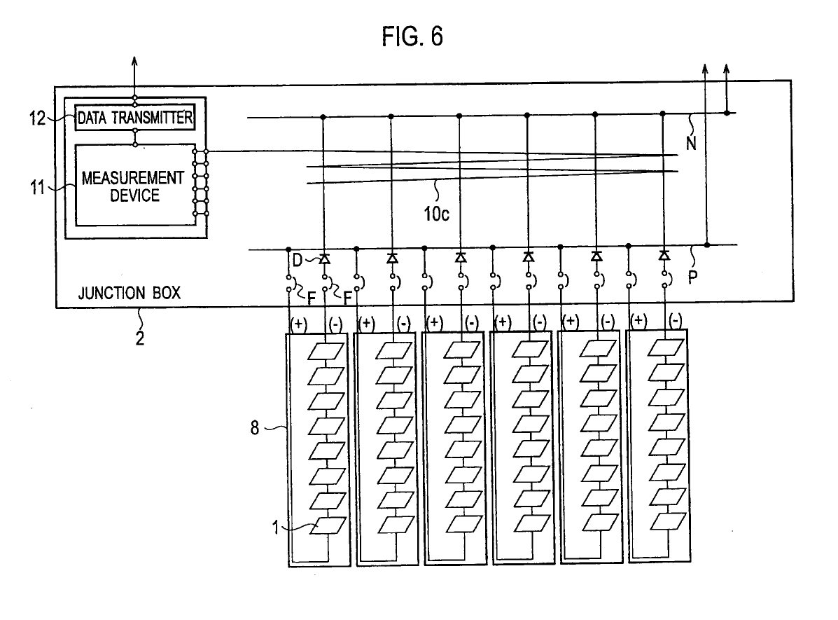

Note that, the DC detector 10c may be provided on the negative electrode terminal (−) side of the solar cell strings 8 and configured to detect the currents flowing into the negative electrode terminals (−) of the solar cell strings 8 as positive values as shown in FIG. 6.

Next, an operation of the photovoltaic power generation system according to the third embodiment, which has the above configuration, will be described. The power generated by each of the solar cell strings 8 is outputted through a corresponding one of the positive electrode terminals (+) and then supplied to the junction box 2. The currents from the respective solar cell strings 8 flow through the fuses F, the DC detector 10c, the back-flow prevention diodes D and the positive electrode P in the junction box 2 and then are outputted outside the junction box 2. During the flow, the DC detector 10c detects the magnitude of the current obtained by adding up the currents outputted from the multiple solar cell strings 8 and sends the result of addition to the measurement device 11 as the current value signal. The measurement device 11 calculates the current value based on the current value signal from each DC detector 10c and sends the current value to the data transmitter 12. The data transmitter 12 transmits the received current value to outside.

In the photovoltaic power generation system described above, if a solar cell module 1 whose output has decreased exists in any of the solar cell strings 8, the current outputted from the solar cell string 8 including the solar cell module 1 is smaller than the currents outputted from the other solar cell strings 8. In this case, the current value detected by the DC detector 10c decreases. As shown in FIG. 8, in a case where the current value detected by the DC detector 10c falls out of an allowable range set in accordance with the purpose, any of the multiple solar cell strings 8 is judged to include a solar cell module 1 whose output has decreased, and is thus detected as abnormal (portion denoted by A in FIG. 8).

As described above, with the photovoltaic power generation system according to the third embodiment, the same effects as those obtained by the photovoltaic power generation system according to the first embodiment or the second embodiment can be obtained. Moreover, since the number of DC detectors can be reduced, a reduction in cost can be achieved.

### Fourth Embodiment

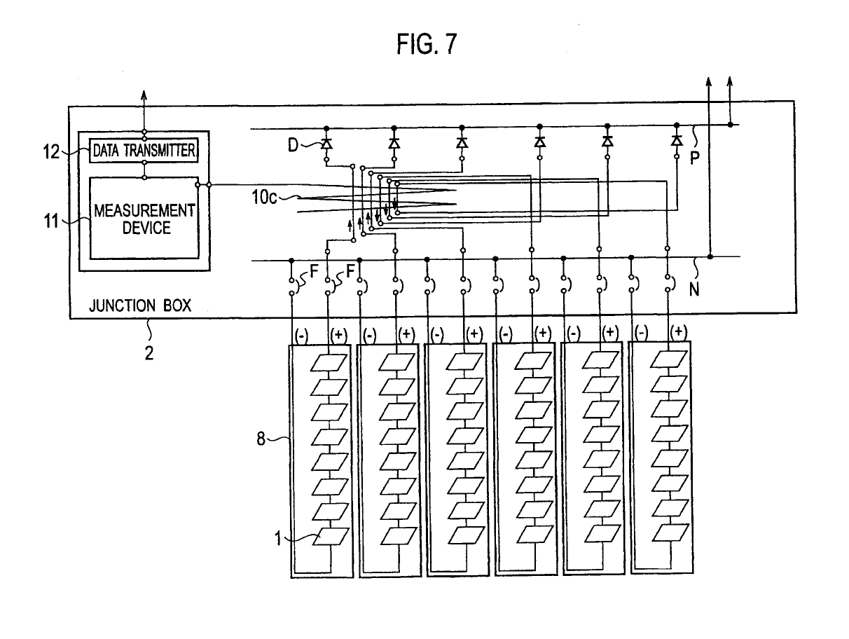

FIG. 7 is a diagram showing a configuration of a main part of a photovoltaic power generation system according to a fourth embodiment. Note that, only the multiple solar cell strings 8 and the junction box 2 are shown in FIG. 7.

This photovoltaic power generation system is different from the photovoltaic power generation system according to the first embodiment only in the internal configuration of the junction box 2. Accordingly, the portion different from the photovoltaic power generation system according to the third embodiment will be mainly described. In other words, the single DC detector 10c is provided to the multiple solar cell strings 8 and configured to detect the currents flowing through all of the positive electrode terminals (+) of the multiple solar cell strings 8 as positive values in the photovoltaic power generation system according to the third embodiment. In contrast, in the photovoltaic power generation system according to the fourth embodiment, the currents flowing out from the positive electrode terminals (+) of part of, e.g., half of the multiple solar cell strings 8 are detected as positive values, and the currents flowing out from the other part of, e.g., the other half thereof are detected as negative values.

In other words, the DC detector 10c is formed of a current transformer, for example, and configured to cause the currents flowing out from the positive electrode terminals (+) of half of the multiple solar cell strings 8 to flow in one direction, then causes the currents flowing out from the positive electrode terminals (+) of the other half thereof to flow in a direction opposite to the one direction to offset the currents and thereby detects the magnitude of the remaining current. In this case, it is preferable to set the number of solar cell strings 8 whose currents are caused to flow in the one direction to be the same as the number of solar cell strings 8 whose currents are caused to flow in the opposite direction. The current value signal indicating the current value detected by the DC detector 10c is sent to the measurement device 11.

Next, an operation of the photovoltaic power generation system according to the fourth embodiment, which has the above configuration, will be described. The power generated by each of the solar cell strings 8 is outputted through a corresponding one of the positive electrode terminals (+) and then supplied to the junction box 2. The currents from the respective solar cell strings 8 flow through the fuses F, the DC detector 10c, the back-flow prevention diodes D and the positive electrode P in the junction box 2 and then are outputted outside the junction box 2. During the flow, the currents outputted from half of the multiple solar cell strings 8 flow through the DC detector 10c in one direction and the currents outputted from the other half of the multiple solar cell strings 8 flow through the DC detector 10c in the opposite direction. As a result, the DC detector 10c detects the magnitude of the current remaining after offsetting the currents flowing in the one direction by the currents flowing in the opposite direction. The DC detector 10c sends the result of offset to the measurement device 11 as the current value signal. Thus, the current to be detected by the DC detector 10c is ideally zero. The measurement device 11 calculates the current value based on the current value signal from the DC detector 10c and sends the current value to the data transmitter 12. The data transmitter 12 sends the received current value to outside.

In a case where the photovoltaic power generation system operates normally, the current values detected by the DC detector 10c are almost equal to each other because the amounts of power outputted from the respective solar cell strings 8 are almost equal to each other. In this case, if the number of the solar cell strings 8 whose currents are caused to flow in the one direction and the number of the solar cell strings 8 whose currents are caused to flow in the opposite direction are set to be the same, the current value of the DC detector 10 inputted to the measurement device 11 becomes almost zero.

If a solar cell module 1 whose output has decreased exists in any of the solar cell strings 8, the current outputted from the solar cell string 8 including the solar cell module 1 is smaller than the currents outputted from the other solar cell strings 8. Here, in a case where the output of the solar cell string 8 including the solar cell module 1 whose output has decreased is detected by the DC detector 10 as a positive value, the current value to be sent to the measurement device 11 decreases. In a case where the output thereof is detected by the DC detector 10 as a negative value, the current value to be inputted to the measurement device 11 increases.

Accordingly, as shown in FIG. 9, in a case where the current value of the DC detector 10 inputted to the measurement device 11 falls out of an allowable range set in accordance with the purpose, the photovoltaic power generation system is judged to include a solar cell module 1 whose output has decreased, and is thus detected as abnormal

As described above, the photovoltaic power generation system according to the fourth embodiment can achieve the functions equivalent to those of the photovoltaic power generation system according to the third embodiment at the equivalent cost. Moreover, the current that needs to be detected by the DC detector 10c is proportional to the number of solar cell modules 1 to be connected to the DC detector 10c in the photovoltaic power generation system according to the third embodiment. For this reason, the detectable current of the DC detector 10c needs to be large. Meanwhile, in the photovoltaic power generation system according to the fourth embodiment, the current to be detected by the DC detector 10c can be reduced to almost zero. Accordingly, the detectable current of the DC detector 10c can be made small, and a reduction in cost can be achieved.

### Fifth Embodiment

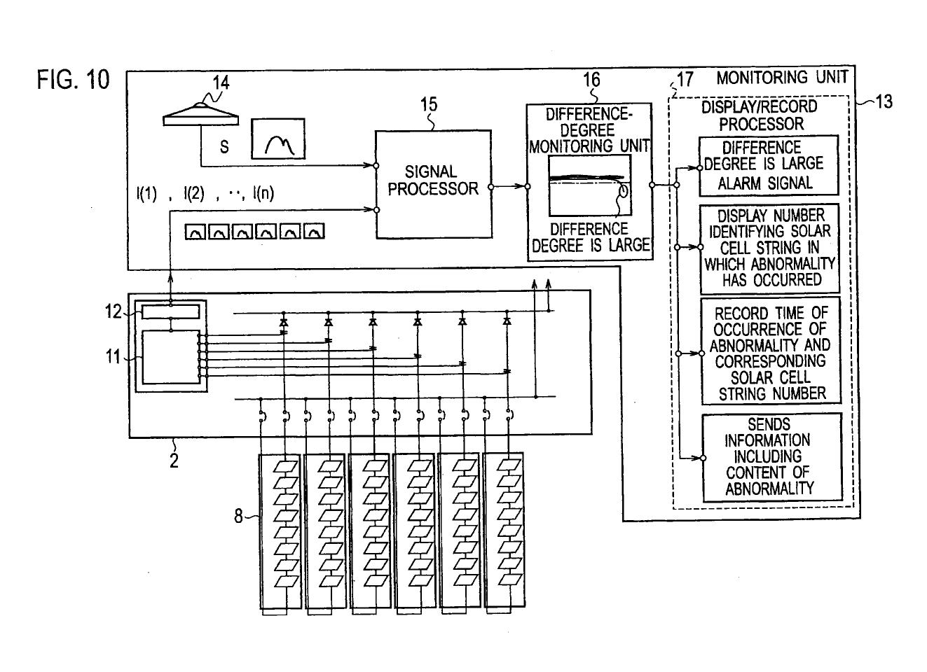

FIG. 10 is a diagram showing a configuration of a main part of a photovoltaic power generation system according to a fifth embodiment. Note that, this photovoltaic power generation system is formed by adding a monitoring unit 13 to the photovoltaic power generation system according to any of the first to fourth embodiments.

The monitoring unit 13 includes a solar irradiance meter 14, a signal processor 15, a difference-degree monitoring unit 16, and a display/record processor 17. The solar irradiance meter 14 measures a solar irradiance and sends the solar irradiance to the signal processor 15 as solar irradiance data.

The signal processor 15 performs predetermined calculations based on the solar irradiance data sent from the solar irradiance meter 14 and the current data sent from the data transmitter 12 of the junction box 2 and sends the result of calculations to the difference-degree monitoring unit 16.

The difference-degree monitoring unit 16 monitors a difference degree of data values based on the result of calculations sent from the signal processor 15. Data indicating a monitoring result of the difference-degree monitoring unit 16 is sent to the display/record processor 17.

In accordance with the data sent from the difference-degree monitoring unit 16, the display/record processor 17 detects the presence of a solar cell module 1 whose output has decreased in the photovoltaic power generation system if the difference degree is large, then outputs an alarm signal while displaying the number identifying the solar cell string 8 in which an abnormality has occurred and also recording the time of occurrence of the abnormality and the corresponding solar cell string number, and then sends information including contents of the abnormality to outside.

Next, an operation of the photovoltaic power generation system according to the fifth embodiment, which has the above configuration, will be described. The current values shown by the current data sent from the data transmitter 12 are I(1), I(2), . . . , I(n). In addition, the solar irradiances shown by the solar irradiance data sent from the solar irradiance meter 14 are S(1), S(2), . . . , S(m).

The signal processor 15 divides the current values I(1), I(2), . . . , sent from the data transmitter 12 I(n) respectively by the solar irradiances S(1), S(2), . . . , S(m), which are measured by the solar irradiance meter 14 located nearest to the solar cell string 8, and sends values Pf(1), Pf(2), . . . , Pf(n), which are obtained by the division to the difference-degree monitoring unit 16. The difference-degree monitoring unit 16 monitors Pf(1), Pf(2), . . . , Pf(n) in a time series, finds a statistical difference degree from a certain preset value, and sends the difference degree to the display/record processor 17.

In a case where the difference degree of a Pf among the Pf(1) to Pf(n) becomes larger than a certain preset threshold, the display/record processor 17 outputs an alarm signal indicating detection of a solar cell module 1 whose output has decreased in the photovoltaic power generation system. The display/record processor 17 displays the solar cell string 8 connected to the Pf whose difference degree has exceeded the threshold, as the solar cell string 8 possibly including the solar cell module 1 whose output has decreased. In addition, the display/record processor 17 records the Pf(1) to Pf(n), the history of alarm signals, and the like.

As described above, with the photovoltaic power generation system according to the fifth embodiment, even in a case where the solar irradiance changes, the presence of a solar cell module 1 whose output has decreased in the photovoltaic power generation system can be detected, and the solar cell string 8 including the solar cell module 1 whose output has decreased can be identified or narrowed down. Thus, the effects obtainable by the photovoltaic power generation system according to any of the first to fourth embodiments can be obtained with higher accuracy.

### Sixth Embodiment

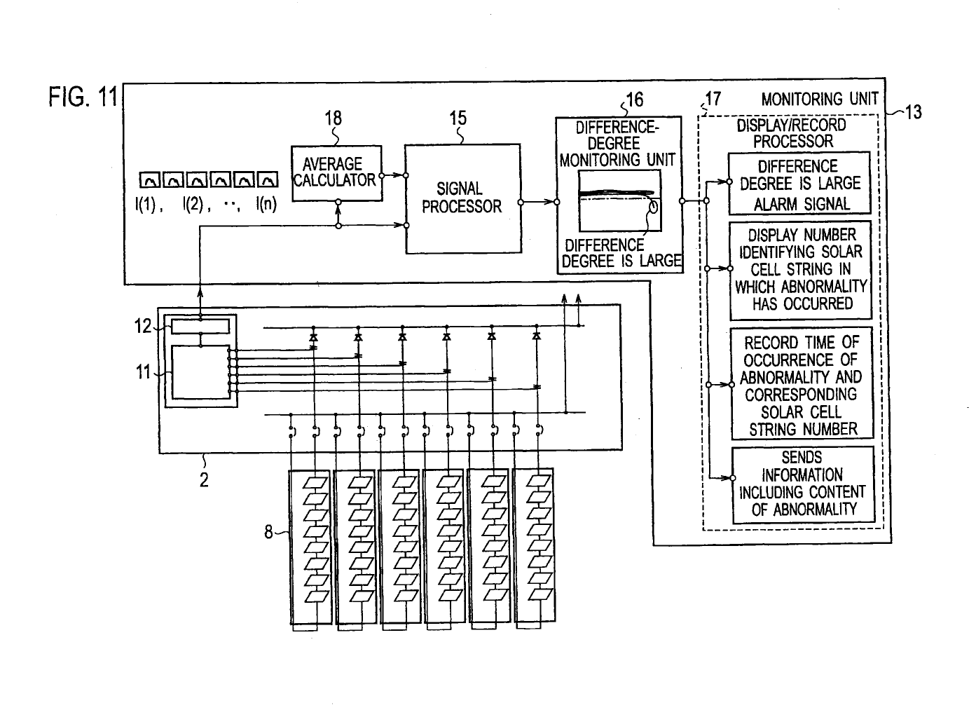

FIG. 11 is a diagram showing a configuration of a main part of a photovoltaic power generation system according to a sixth embodiment. Note that, this photovoltaic power generation system is formed by removing the solar irradiance meter 14 from the monitoring unit 13 of the photovoltaic power generation system according to the fifth embodiment and adding an average calculator 18 thereto. The average calculator 18 calculates an average Ave of the current values I(1), I(2), . . . , I(n), which are sent from the data transmitter 12. This average Ave calculated by the average calculator 18 is sent to the signal processor 15.

Next, an operation of the photovoltaic power generation system according to the sixth embodiment, which has the above configuration, will be described. The current values shown by the current data sent from the data transmitter 12 are I(1), I(2), . . . , I(n).

The average calculator 18 calculates the average value Ave=ΣI(k)/n of the current values I(1), I(2), . . . , I(n), which are sent from the data transmitter 12, and sends the average value Ave to the signal processor 15. The signal processor 15 sends the current values I(1), I(2), . . . , I(n), which are sent from the data transmitter 12, to the difference-degree monitoring unit 16 and also sends the average value Ave, which is sent from the average calculator 18, to the difference-degree monitoring unit 16.

The difference-degree monitoring unit 16 monitors, in a time series, the current values I(1) to (n), which are sent from the data transmitter 12, finds a statistical difference degree from the average value Ave, which is sent from the average calculator 18 via the signal processor 15, and sends the difference degree to the display/record processor 17. In a case where the difference degree of a current value I among the current values I(1), I(2), . . . , I(n) becomes larger than a certain preset threshold, the display/record processor 17 outputs an alarm signal indicating detection of a solar cell module 1 whose output has decreased in the photovoltaic power generation system. The display/record processor 17 displays the solar cell string 8 connected to the DC detector detecting the current value whose difference degree has exceeded the threshold, as the solar cell string 8 possibly including the solar cell module 1 whose output has decreased. In addition, the display/record processor 17 records the current values I(1), I(2), . . . , I(n), the history of alarm signals, and the like.

As described above, the photovoltaic power generation system according to the sixth embodiment can achieve the functions equivalent to those of the photovoltaic power generation system according to the fifth embodiment while omitting the solar irradiance meter 14. Thus, the photovoltaic power generation system at low cost can be achieved.

### Seventh Embodiment

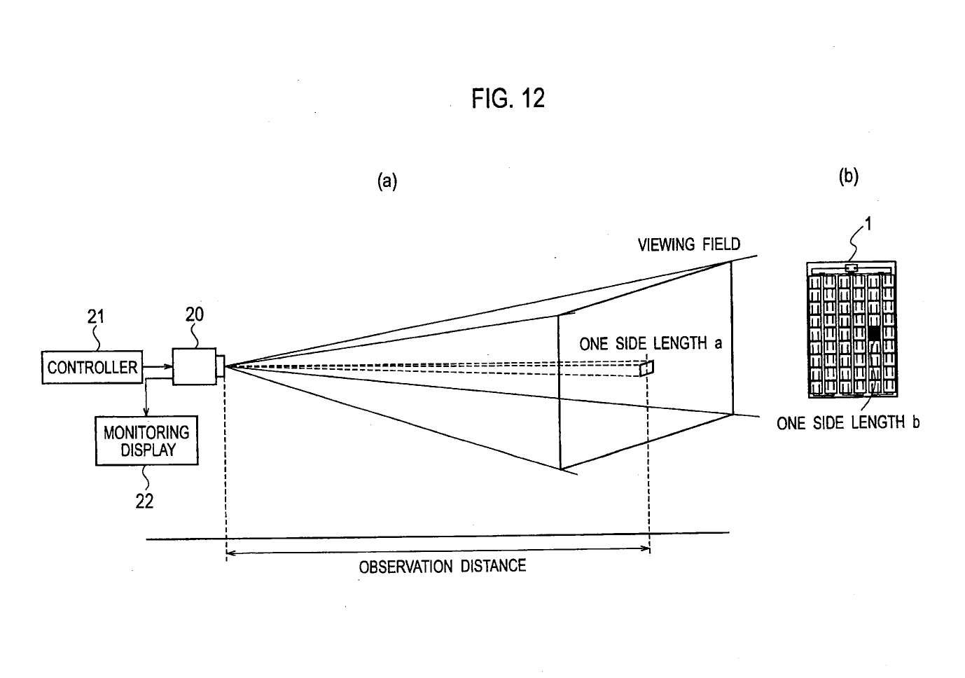

FIG. 12 is a diagram for describing an imaging device used in a photovoltaic power generation system according to a seventh embodiment. An imaging device 20 is formed of an infrared camera and has a function to capture visible light and infrared light.

The imaging device 20 is formed of a high-definition CCD camera, for example, and captures an image by visible light, and also detects and visualizes infrared rays in red or the like and displays the infrared rays on a monitoring display 22 in accordance with an instruction from a controller 21 formed of a microcomputer for example.

An image captured by the imaging device 20 described above is formed of multiple pixels. The number of pixels, the distance to the observation target, and the focal distance of the lens of the imaging device 20 uniquely determine the minimum detection size of the image of a detectable observation target. In other words, when the distance from the observation target increases, the minimum detection size becomes large. In an attempt to capture a heat generating position of a solar cell module 1 in an image, it becomes difficult to identify a solar cell generating heat if a minimum detection size a becomes larger than a size b of the image of a single solar cell.

In a case where a solar cell array is inspected using images, the image is preferably captured from a long distance. This is because the number of images to be captured is reduced and the inspection time is also shortened. However, if the distance is too long, a single solar cell can be no longer captured by a single pixel as described above, and the detection accuracy is thus reduced.

Thus, the imaging device 20 is placed in a position where the size of a single pixel of an image obtained by capturing the surface of the solar cell array by using infrared rays, i.e., the minimum detection size a becomes smaller than the size b of the image of a single solar cell.

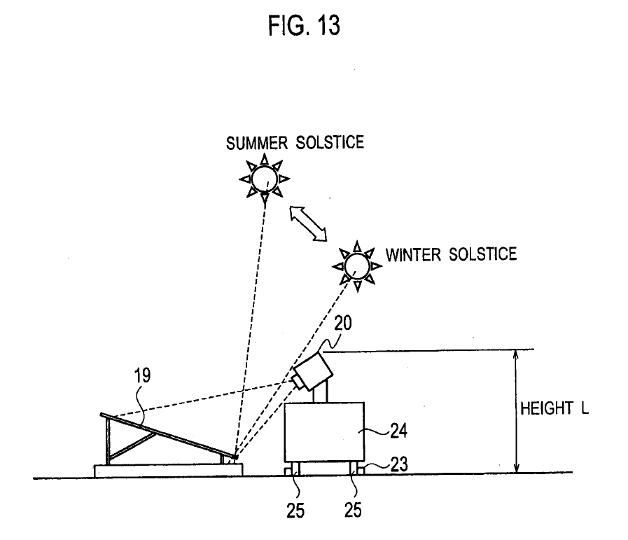

FIG. 13 is a lateral view showing a configuration of a photovoltaic power generation system according to the seventh embodiment. In a case where inspection is performed using an image of a solar cell array 19, the presence of a heat generating object located near the solar cell array 19 in the captured image, or the presence of the shadow of the observing system in the captured image may affect the result of the inspection. Accordingly, in order to improve the inspection accuracy, it is preferable to obtain a good image to the utmost extent.

In the photovoltaic power generation system shown in FIG. 13, rails 23 are laid so as to keep a distance from the solar cell array 19 to the imaging device 20 constant, and the observing system is moved along the rails 23. The observing system is formed of the imaging device 20, a movable carriage 24 on which the imaging device 20 is installed, and tires 25 provided to the movable carriage 24.

In addition, in order to prevent the shadow of the imaging device 20 installed on the movable carriage 24 from being captured in the images even at the winter solstice, i.e., when the culmination altitude is lowest throughout the year, a height L of the observing system is limited. Note that, the rails 23, the movable carriage 24 and the tires 25 correspond to a moving mechanism.

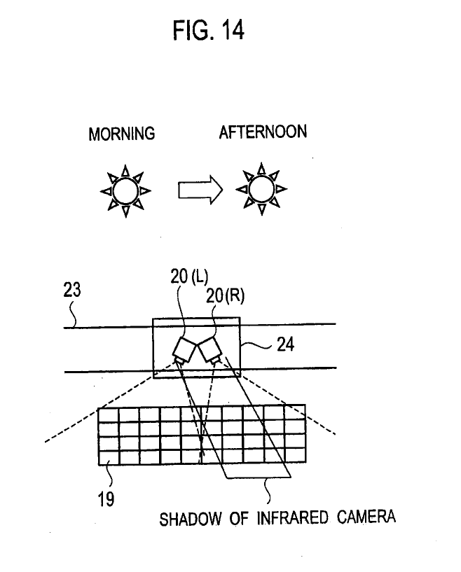

FIG. 14 is a top view showing a configuration of a modification example of the photovoltaic power generation system according to the seventh embodiment. As shown in this photovoltaic power generation system, two imaging devices 20 are installed. The imaging devices 20 can be arranged in such a way that the shadow of the observing system is not captured in the images captured by either one of the imaging devices 20. FIG. 14 shows an example in which no shadow is captured in the images captured by the imaging device 20 (L). The images obtained in this manner are favorable in performing image processing. Note that, the images may be captured as still images or moving images.

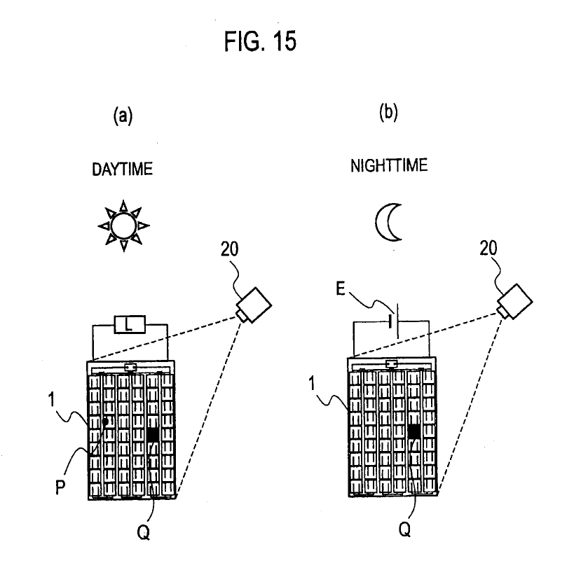

FIG. 15 is a diagram for describing an example of an operation of the photovoltaic power generation system according to the seventh embodiment. As shown in FIG. 15(a), if the surface of the solar cell array 19 is captured by the imaging device 20 during daytime power generation, that is, during a period when a load L is supplied with DC power, a temperature rise in part of solar cells or wiring portions may be found.

This is because a phenomenon (hot spot) Q is observed, which occurs, in a case where a mismatch in short-circuit current occurs due to variation in the performance of the solar cells, a crack on a wire connection portion, or a local shadow (attachment P of a non-transparent object onto the surface of the solar cell panel) or the like, and thus the solar cell acts as an electrical load and generates abnormal heat due to an increase in resistance.

Meanwhile, as shown in FIG. 15(b), the heat generation due to a local shadow as observed in capturing images during daytime does not occur when the solar cell array 19 is captured by the imaging device 20 with an electric current flowing through the solar cell array 19 from a DC power source E during nighttime while power generation is stopped. Here, only an image of heat generation due to a failure in the solar cell array 19 such as a crack on a wire connection portion is obtained.

As described above, such comparison between the image captured while the power generation is performed and the image captured while the power generation is stopped makes it possible to eliminate the influence of a local shadow due to attachment of a non-transparent object onto the surface of the solar cell panel, for example. Thus, the inspection accuracy of the photovoltaic power generation system can be improved.

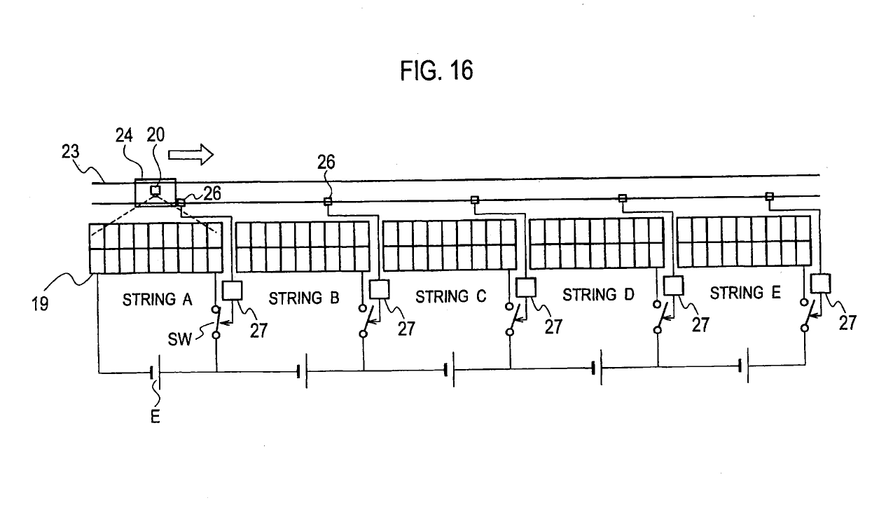

FIG. 16 is a diagram showing a configuration of another modification example of the photovoltaic power generation system according to the seventh embodiment. This photovoltaic power generation system includes position sensors 26 near multiple positions of one of the rails 23, the positions respectively corresponding to multiple strings A to E, which are constituent components of the solar cell array 19. In addition, the photovoltaic power generation system includes switches SW configured to control whether DC power is to be supplied to the respective strings from the DC power supply E or not, and controllers 27 configured to generate signals to control opening and closing of the respective switches SW in accordance with the signals sent from the respective position sensors 26.

In the above configuration, when any of the position sensors 26 detects the movable carriage 24 moving on the rails 23, a signal indicating the detection thereof is sent to a corresponding one of the controllers 27. Upon receipt of the signal from the position sensor 26, the controller 27 generates a signal to open a corresponding one of the switches SW and sends the signal to the corresponding switch SW. Accordingly, only the string facing the movable carriage 24 on which the imaging device 20 is installed (observing system) is supplied with a current from the DC power supply E. With this configuration, only the string near the observing system is energized. Thus, it is economical as compared with a case where the current is caused to flow through all the strings.

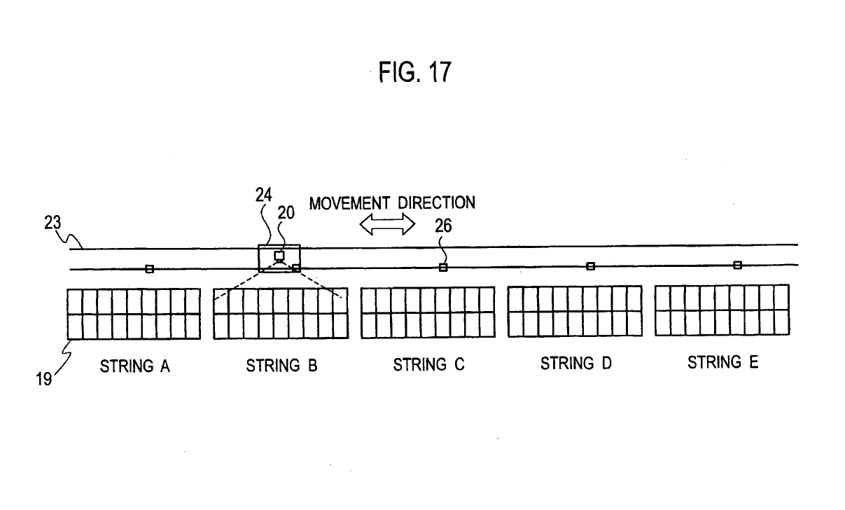

FIG. 17 is a diagram showing a configuration of still another modification example of the photovoltaic power generation system according to the seventh embodiment. In this photovoltaic power generation system, a self-running device is provided to the observing system, and the observing system is automatically moved by controlling the self-running device by remote operation. Accordingly, the images of the respective strings are captured by the imaging device 20, and the images obtained by the capturing are analyzed. In accordance with the result of the analysis, if there is an image including a heat level exceeding a preset threshold, the corresponding string is judged as a failed string, and the result of the judgment is displayed.

The processing from the analysis of the images to the display of the result can be performed by using functions included in the imaging device 20. Note that, this processing can be also performed by using software configured to capture images into a personal computer and analyze the images, for example. With this configuration, the inspection can be performed automatically or semi-automatically. Thus, the work load required for the inspection can be reduced.

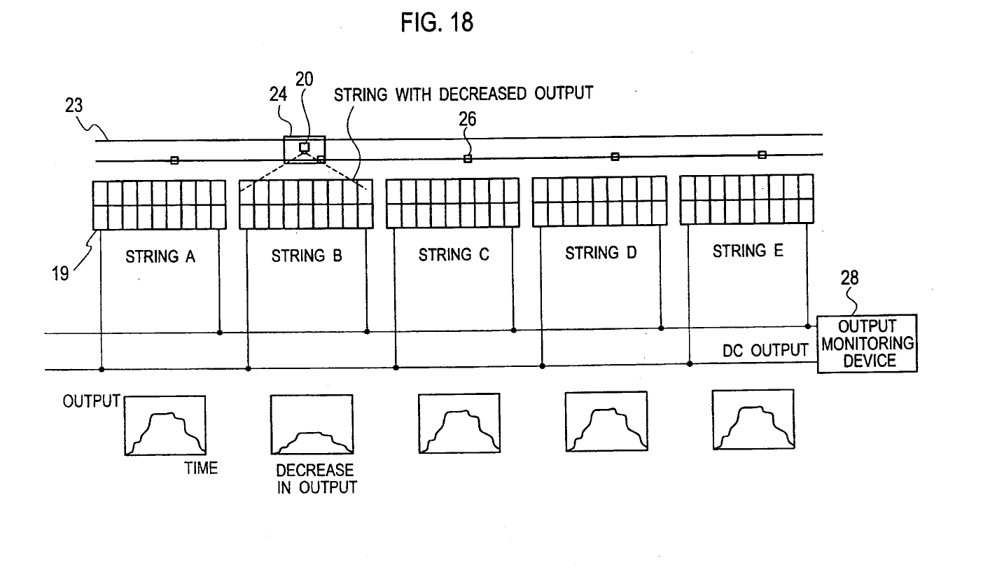

FIG. 18 is a diagram showing a configuration of yet another modification example of the photovoltaic power generation system according to the seventh embodiment. This photovoltaic power generation system includes the self-running device provided to the observing system and also includes an output monitoring device 28, which monitors the output of each of the multiple strings A to E. In a case where the output monitoring device 28 detects a decrease in the output of any of the strings, the self-running device moves the observing system to the position facing the string in which a decrease in the output is detected. The imaging device 20 captures the string, and the image obtained by the capturing is analyzed.

In accordance with the result of the analysis, if there is an image including a heat level exceeding a preset threshold, the corresponding string is judged as a failed string, and the result of the judgment is displayed. With this configuration, the inspection can be performed automatically or semi-automatically. Thus, the work load required for the inspection can be reduced.

### Eighth Embodiment

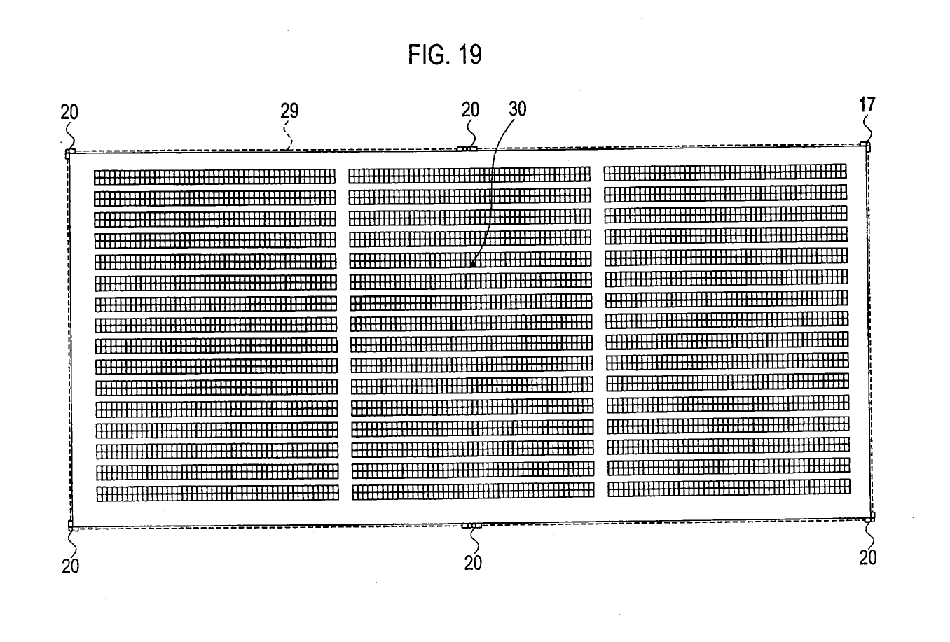

FIG. 19 is a diagram partially showing a configuration of an intrusion monitoring system used with a photovoltaic power generation system according to an eighth embodiment. The intrusion monitoring system monitors an intruder entering a solar cell array area 29. In this intrusion monitoring system, multiple imaging devices 20 are arranged around the solar cell array area 29 in such a way that no gap is formed between the viewing fields of the imaging devices 20. In addition, the imaging devices 20 capture the solar cell array area 29 at certain time intervals or continuously in order that an intruder entering the solar cell array area 29 can be recognized, and record the images obtained by the capturing.

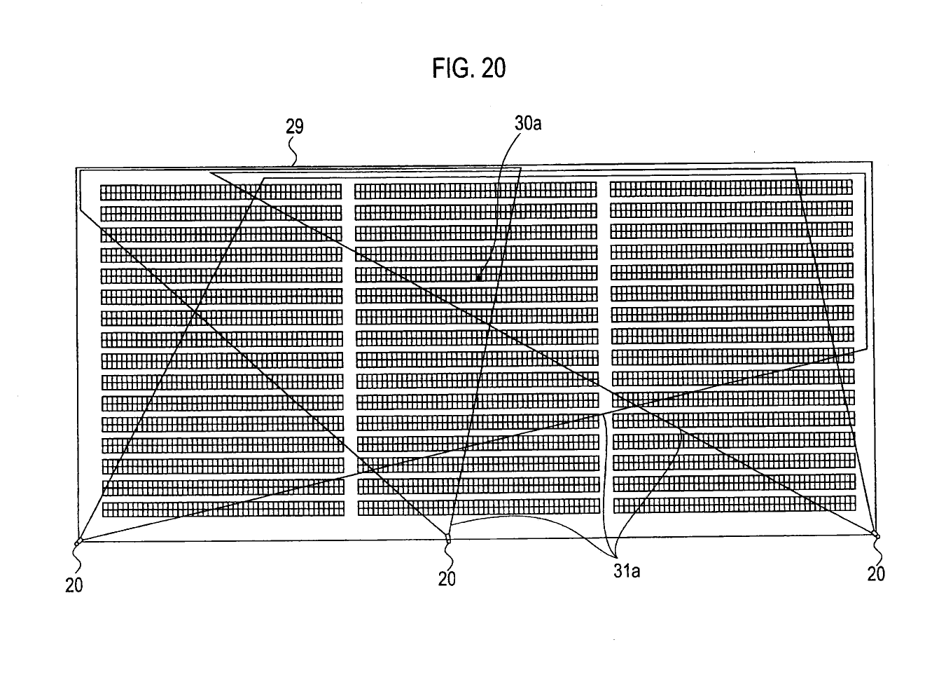

FIG. 20 is a diagram partially showing a configuration of a photovoltaic power generation system configured to search for a high temperature portion 30a of solar cell modules 1 by an imaging device arranged with the multiple imaging devices 20 of the intrusion monitoring system shown in FIG. 19 or by the multiple imaging devices 20. In this photovoltaic power generation system, each of the imaging devices 20 includes a function to capture visible light and infrared light.

The imaging devices 20 are each formed of a high definition CCD camera capable of capturing high resolution images and of telephotography through a lens, and perform detection and visualization of infrared rays in red in addition to capturing of images using visible light. The images thus captured are displayed on the monitoring display 22. Although a viewing field 31a of each of the imaging devices 20 is a constant range, the imaging device 20 is capable of monitoring a wide area because the imaging device 20 is rotatable.

In the photovoltaic power generation system shown in FIG. 20, upon detection of the high temperature portion 30a by using infrared rays while monitoring the surface of the solar cell modules, which are constituent components of the solar cell array, the imaging device 20 adjusts its rotation angle in order that the high temperature portion 30a can be located at the center in the left and right direction of the viewing field of the imaging device 20. The user can visually identify the location of the high temperature portion 31a of the solar cell modules by viewing an image of the solar cell array area 29 and the periphery thereof displayed on the monitoring display 22.

With this configuration, the user can know the location of a solar cell module that has failed and thus formed the high temperature portion 31a in the solar cell array area.

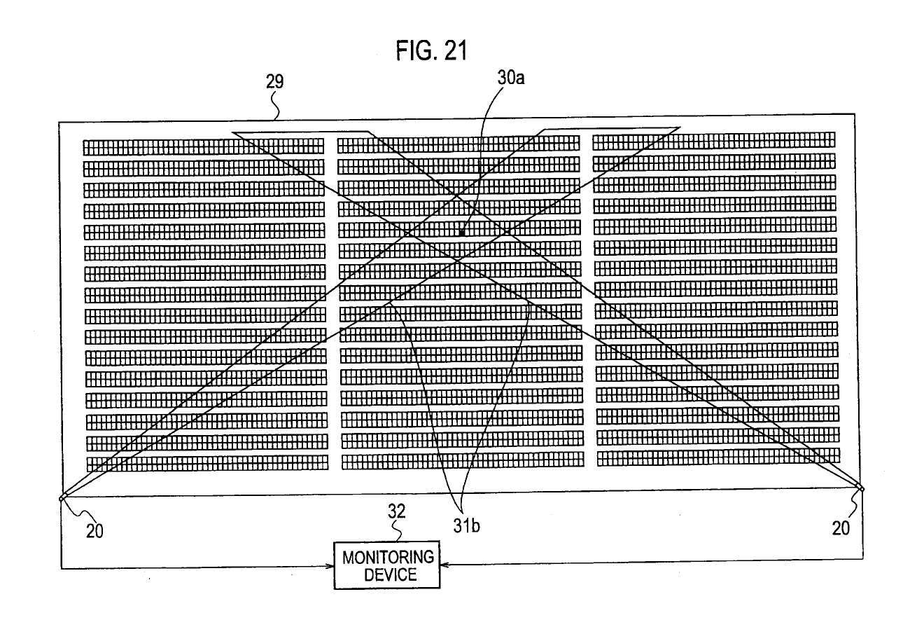

FIG. 21 is a diagram partially showing a configuration of the photovoltaic power generation system according to the eighth embodiment. This photovoltaic power generation system includes two imaging devices 20 at left and right of a side of the solar cell array area 29. Each of the two imaging devices 20 includes an angle detection mechanism (illustration is omitted) configured to scan the solar cell array area 29 while being rotated by a rotation mechanism (illustration is omitted), detect the high temperature portion 30a of the solar cell modules by using infrared rays and detect the rotation angle. The rotation mechanism corresponds to a moving mechanism.

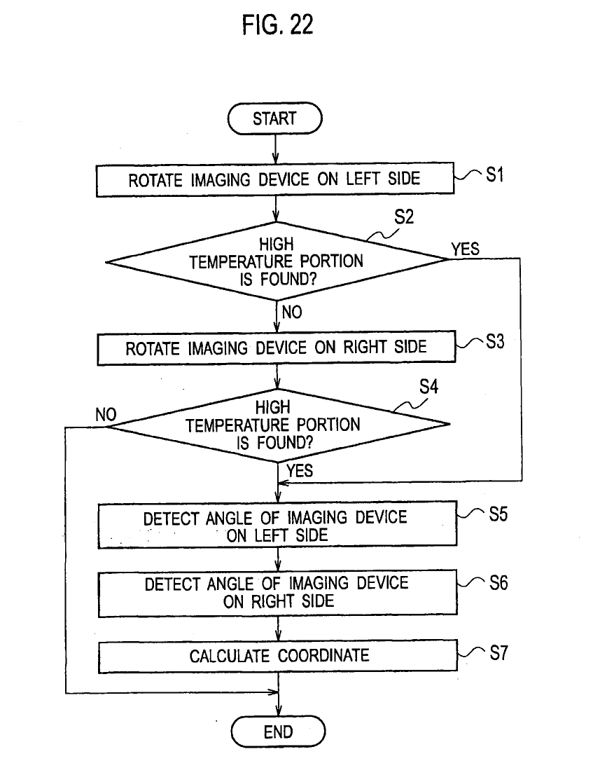

Next, an operation of the photovoltaic power generation system according to the eighth embodiment will be described with reference to a flowchart shown in FIG. 22. First, the imaging device 20 on the left side is rotated (step S1). In other words, the imaging device 20 is rotated by the not illustrated rotation mechanism. Next, whether or not a high temperature portion is found is checked (step S2).

In other words, the imaging device 20 performs monitoring while capturing the surfaces of the solar cell modules, and whether or not the high temperature portion 30a is detected by using infrared rays during this monitoring is checked. If the high temperature portion 30a is found in step S2, the imaging device 20 adjusts its rotation angle by the rotation mechanism in order that the high temperature portion 30a can be located at the center in the left and right direction of the viewing field. Thereafter, the processing proceeds to processing in step S5.

Meanwhile, if no high temperature portion is found in step S2, the imaging device 20 on the right side is rotated (step S3). The processing in step S3 is the same as the processing in step S1 described above. Next, whether or not a high temperature portion is found is checked (step S4). The processing in step S4 is the same as the processing in step S2 described above. If the high temperature portion 30a is found in step S4, the imaging device 20 adjusts its rotation angle by the rotation mechanism in order that the high temperature portion 30a can be located at the center in the left and right direction of the viewing field. Thereafter, the processing proceeds to processing in step S5.

In step S5, the angle of the imaging device 20 on the left side is detected. In other words, the rotation angle of the imaging device 20 on the left side at this time is detected by the angle detection mechanism and sent to the monitoring device 32 as rotation angle information. Subsequently, the angle of the imaging device 17 on the right side is detected (step S6). In other words, the rotation angle of the imaging device 20 on the right side at this time is detected by the angle detection mechanism and sent to the monitoring device 32 as rotation angle information.

Next, coordinates are calculated (step S7). In other words, upon transmission of the rotation angle information at detection of the high temperature portion 30a of the solar cell modules from each of the two imaging devices 20, the monitoring device 32 finds an intersection point of the two rotation angle directions each indicated by the rotation angle information. Accordingly, this intersection point is associated with a position in the solar cell array area 7, and the positional coordinates of the high temperature portion 30a of the solar cell modules obtained as a result of the association are displayed on the monitoring display 22.

With this configuration, the user can know the location of a solar cell module that has failed and thus formed the high temperature portion 30a in the solar cell array area.

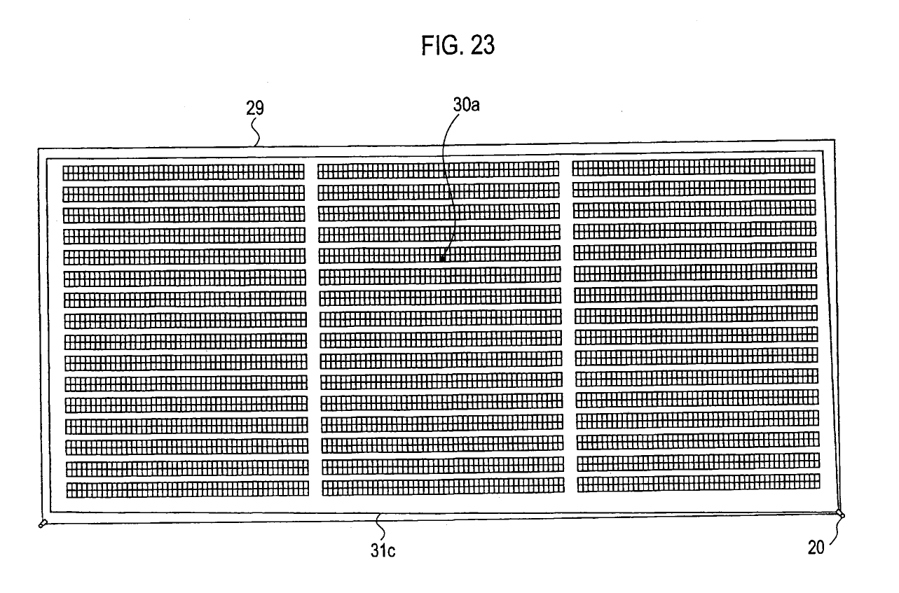

FIG. 23 is a diagram partially showing a configuration of a modification example of the photovoltaic power generation system according to the eighth embodiment. This photovoltaic power generation system includes one imaging device 20. The imaging device 20 includes a wide-angle lens and is thus capable of monitoring the entire region of the solar cell array area 29. In addition, although illustration is omitted, addresses are displayed on location display boards provided to some locations in the solar cell array area 29.

In the photovoltaic power generation system shown in FIG. 23, the imaging device 20 simultaneously monitors the entire region of the solar cell array area 29 and displays the region on the monitoring display 22. Upon detection of the presence of a high temperature portion in the region being monitored by using infrared rays, the imaging device 20 captures the address on a corresponding one of the location display boards by visible light and displays the address on the monitoring display 22. Accordingly, the location of the faulty module is identified.

With this configuration, the user can know the location of a solar cell module 1 that has failed and thus formed the high temperature portion 30a in the solar cell array area 29.

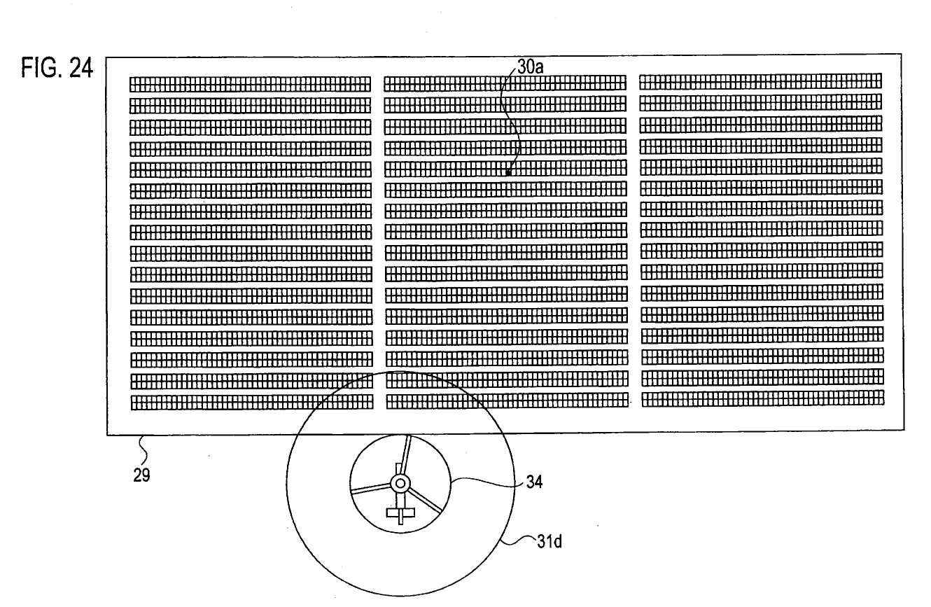

FIG. 24 is a diagram partially showing a configuration of another modification example of the photovoltaic power generation system according to the eighth embodiment. In the photovoltaic power generation system, the imaging device 20 is installed on an unmanned flight device 34 and thus configured to detect the high temperature portion 30a formed by failure of a solar cell module, while flying over the solar cell array area 29, and identify the location of the faulty solar cell module from the location information displayed on the solar cell array area.

In the photovoltaic power generation system shown in FIG. 24, the imaging device 20 installed on the unmanned flight device 34 sequentially searches over the solar cell array area 29 and detects by using infrared rays the high temperature portion 30a formed by failure of a solar cell module 1. The location information shown near the faulty solar cell module and captured using visible light is displayed on the monitoring display 22. The user identifies the location of the faulty solar cell module by visually observing the contents displayed on the monitoring display 22.

With this configuration, the user can know the location of a solar cell module 1 that has failed and thus formed the high temperature portion 30a in the solar cell array area 29.

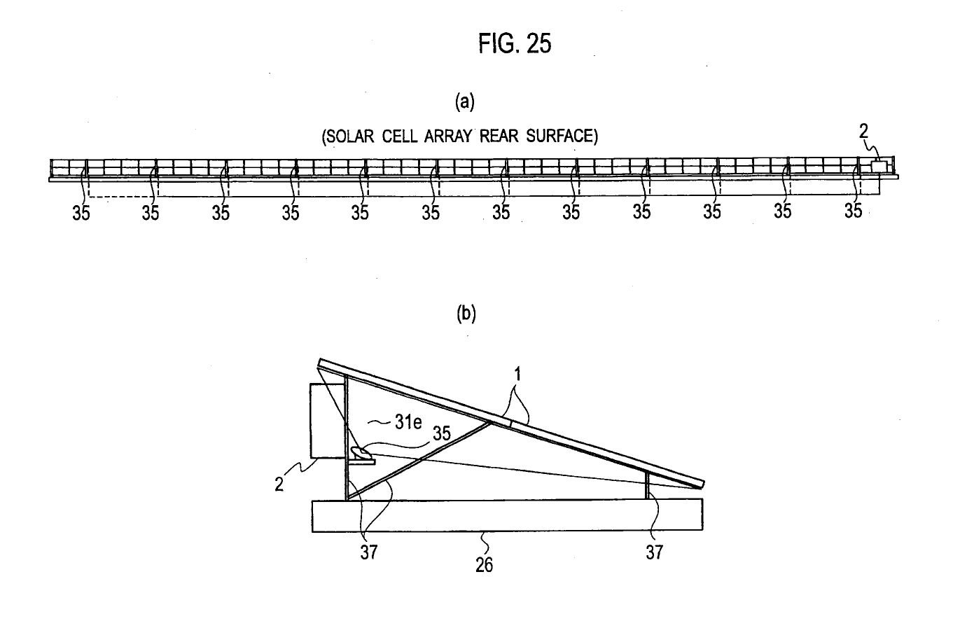

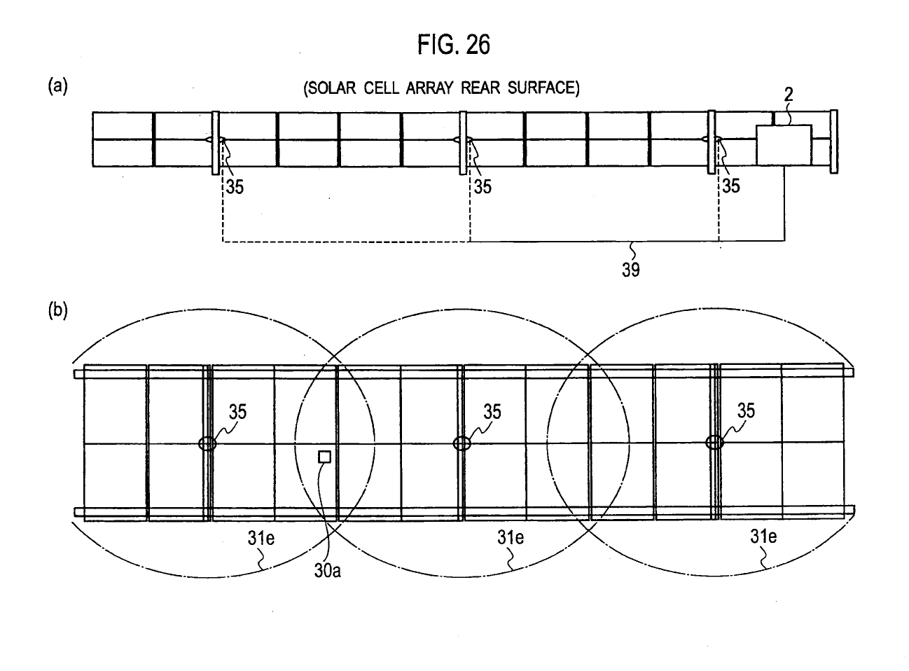

FIG. 25 is a diagram partially showing a configuration of still another modification example of the photovoltaic power generation system according to the eighth embodiment. FIG. 25(a) shows how wide-angle lens infrared imaging devices 35 each configured to monitor the rear surface of a corresponding solar cell module are arranged on the solar cell array 19. In this photovoltaic power generation system, the wide-angle lens infrared imaging devices 35 are installed on mounts 37 provided on a base 36. FIG. 26(a) and FIG. 26(b) show a configuration in which multiple wide-angle lens infrared imaging devices 35 each configured to monitor the rear surface of a corresponding solar cell module are installed on the mounts 37.

In the photovoltaic power generation system shown in FIG. 25, the wide-angle lens infrared imaging devices 35 monitor the rear surface of the solar cell array 19 while capturing the rear surface thereof. Thus, a high temperature on the rear surface of a faulty solar cell module is detected, and the detection information is displayed on the monitoring display 22 while the location information of the solar cell module in which the high temperature portion 30a is detected is also displayed on the monitoring display 22.

With this configuration, the user can know the location of a solar cell module 1 that has failed and thus formed the high temperature portion 30a in the solar cell array area 29.

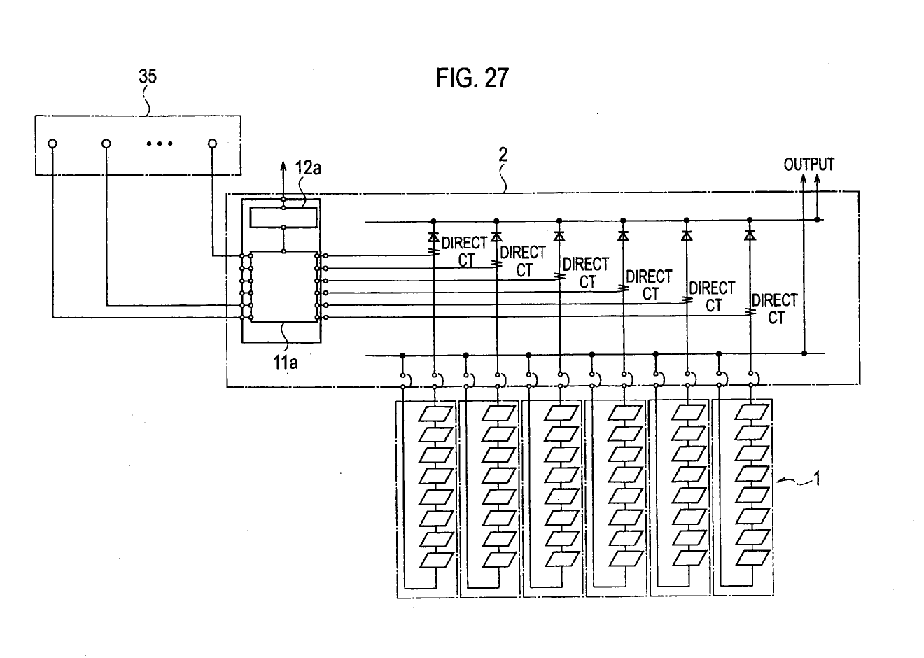

FIG. 27 is a diagram partially showing a configuration of yet another modification example of the photovoltaic power generation system according to the eighth embodiment. This photovoltaic power generation system includes multiple wide-angle lens infrared imaging devices 35 arranged along the mounts 37, a measurement device 11a, a transmitter 12a, and direct CTs (current transformers) each configured to measure a DC current of a corresponding one of strings 1 each formed of solar cell modules connected in series. The measurement device 11a, the transmitter 12a, and the direct CTs are installed in the junction box 2.

In this photovoltaic power generation system, the multiple wide-angle lens infrared imaging devices 35 monitor the rear surfaces of all of the solar cell modules and send signals indicating captured images to the measurement device 11a. In addition, the multiple direct CTs send signals indicating measured DC currents generated by the multiple strings to the measurement device 11a.

The measurement device 11a generates signals obtained by converting the signals from the multiple wide-angle lens infrared imaging devices 35 and the signals from the multiple direct CTs into an arrangement of predetermined signal information and sends the signals to an upper-level monitoring device (not illustrated) via the transmitter 12a at previously set time intervals.

The upper-level monitoring device identifies a solar cell module outputting a DC current differing from the other current values at least by a predetermined preset value. If a solar cell module having a high temperature exists in the images obtained from the multiple wide-angle lens infrared imaging devices 35, the upper-level monitoring device determines the location of the solar cell module.

Accordingly, the location of the faulty solar cell module is identified on the basis of the images obtained from the multiple wide-angle lens infrared imaging devices 35 and the signals obtained from the multiple direct CTs, and the location information is displayed on the monitoring display 22.

With this configuration, the user can surely know the location of the solar cell module in the solar cell array area, the solar cell module including a high temperature portion formed by failure and having an output current smaller than those of the other solar cell modules.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and spirit of the inventions.

1. (canceled)

2. A method for detecting abnormality of a solar cell array comprising the steps of:
capturing, by an imaging device using infrared rays, a first image of a surface of the solar cell array in a state that an electric current generating electricity is being supplied to outside;
capturing, by an imaging device using the infrared rays, a second image of the surface of the solar cell array in a state that the electric current is being supplied from outside;
displaying the first and second images.

3. The method for detecting abnormality of the solar cell array according to claim 2, wherein
a size of a single pixel of the first and second images is smaller than a size of an image of a single solar cell.

4. The method for detecting abnormality of the solar cell array according to claim 2, wherein
the first and second images are moving images or still images.

5. The method for detecting abnormality of the solar cell array according to claim 2, wherein
the image device is moved by a moving mechanism.

6. The method for detecting abnormality of the solar cell array according to claim 5, wherein
the moving mechanism is an unmanned flight device.

7. The method for detecting abnormality of the solar cell array according to claim 6, wherein the imaging device installed on the unmanned flight device detects a faulty solar cell array by using infrared rays, said method further comprising:
capturing location information of a location near the faulty solar cell array using visible light; and
displaying on a display device the location information captured using visible light.
